(19) United States
(12) Patent Application Publication
(10) Pub. No.: US 2014/0289576 A1
(43) Pub. Date: Sep. 25, 2014

(54) SEMICONDUCTOR INTEGRATED CIRCUIT AND METHOD FOR SELF TEST OF SEMICONDUCTOR INTEGRATED CIRCUIT

(71) Applicant: KABUSHIKI KAISHA TOSHIBA, Tokyo (JP)

(72) Inventor: Tomoyuki Maekawa, Kanagawa (JP)

(73) Assignee: KABUSHIKI KAISHA TOSHIBA, Tokyo (JP)

(21) Appl. No.: 14/192,810

(22) Filed: Feb. 27, 2014

(30) Foreign Application Priority Data
Mar. 25, 2013 (JP) 2013-062228

(51) Int. Cl. G01R 31/3177

(52) U.S. Cl. CPC G01R 31/3177
USPC 714/727

(57) ABSTRACT

Certain embodiments provide a semiconductor integrated circuit comprising: a logic circuit including combination circuits and first flip-flops; plural selectors for respective first flip-flops configured to switch between first paths from the combination circuits and second paths from previous stage flip-flops of the first flip-flops; plural scan chains in the logic circuit, each of the scan chains configured to have the second path activated by the selectors; a pattern generator configured to generate patterns for test for the scan chains; a test control circuit configured to control the pattern generator and the plural selectors, the test control circuit performing self test; and plural setting terminals configured to set logic values individually in a combination of a part of second flip-flops which are representative of a logic pattern and of the first flip-flops in the logic circuit, the setting flip-flops being representative of a logic pattern.

### CROSS-REFERENCE TO RELATED APPLICATION

The present application claims priority under 35 U.S.C. 119 to Japanese Patent Application Ser. No. 2013-062228, filed on Mar. 25, 2013, the entire disclosure of which is incorporated herein by reference.

### FIELD

An embodiment relates to a semiconductor integrated circuit and a method for self test of the semiconductor integrated circuit.

### BACKGROUND

As one of easier methods for resolving the difficulty of testing a large-scale and complex LSI, logic BIST (Built-In Self Test) (self test by a built-in logic circuit) is predominant in recent years.

The logic BIST generates test patterns to be supplied to a circuit block under test. The logic BIST analyzes output of test result from the block under test. The logic BIST fully automatically performs the generation of the test patterns and the analysis of the output of test result by a logic circuit in the LSI. The logic circuit is configured near the block under test. For example, a method is known in which a scan chain made up of flip-flop circuits are used to identify where a fault is.

In the block under test to which the logic BIST is directed, there is provided a scan chain in the same manner as the scan test of a related art. The logic BIST shifts test data into the scan chain. Data which have a length corresponding to the length of the chain is shifted in. When the shift in is finished, the logic BIST performs launch and capture at a system clock frequency. That is, the block under test is tested at an actual operation speed.

At the launch, the logic BIST supplies a Launch Clock for generating data transition to the flip-flops. In the capture following the launch, the logic BIST supplies a Capture Clock to the flip-flops. The Capture Clock is for capturing the result. By a basic operation using the two clocks, the logic BIST captures data.

The logic BIST shifts thus captured data out at the next shift in. The logic BIST inputs the shifted out result into a data compressor. The data compressor is called as an MISR (Multi-Input Shift Register). The test of the block under test is executed by comparing the value from the compressor with an expected value after a predetermined number of shift ins and shift outs are performed.

### BRIEF DESCRIPTION OF THE DRAWINGS

FIG. 1 is a circuit block diagram of a semiconductor integrated circuit according to a first embodiment;

FIG. 2 is a circuit block diagram of one scan chain of the semiconductor integrated circuit according to the first embodiment;

FIGS. 3A to 3C are diagrams showing a structural example of flip-flops used in the semiconductor integrated circuit according to the first embodiment;

FIG. 4 is a circuit diagram showing a specific example of the semiconductor integrated circuit according to the first embodiment;

FIGS. 5A to 5K are timing charts of an operation of self test performed by a test control circuit of the semiconductor integrated circuit according to the first embodiment;

FIG. 6 is a circuit diagram showing a specific example of a semiconductor integrated circuit according to a second embodiment;

FIGS. 7A to 7L are timing charts of an operation of self test performed by a test control circuit of the semiconductor integrated circuit according to the second embodiment;

FIG. 8 is a circuit diagram showing a specific example of a semiconductor integrated circuit according to a third embodiment;

FIGS. 9A to 9K are timing charts of an operation of self test performed by a test control circuit of the semiconductor integrated circuit according to the third embodiment;

FIG. 10 is a circuit diagram of a specific example of a semiconductor integrated circuit according to a fifth embodiment; and

FIGS. 11A to 11K are timing charts of an operation of self test of a test control circuit of the semiconductor integrated circuit according to the fifth embodiment.

### DETAILED DESCRIPTION

In the self test performed by the logic BIST, however, to improve a fault detection rate is not easy, because the test patterns use random data. To surely detect a fault at a desired place is difficult. A seed value of a seed given for a pseudorandom number may be changed. Yet to back-calculate the seed value is very difficult. Even if the seed value can be calculated, the self test by the logic BIST is required to recalculate the seed value every time the circuit is modified during a development stage. There are also other problems of increase in development duration and decrease in development efficiency.

In addition, to improve a fault detection rate is not easy as described above. To put a test point/test points in the self test using logic BIST is highly required. The test point indicates a terminal or a signal line. The test point/points are put in a circuit to monitor signals in the circuit which are difficult to monitor from outside the circuit. But the test point/points put in a path of critical timing separate the path in mid-course. When the data path is separated, to perform the test at an actual operation speed is impossible.

Moreover, many flip-flops are simultaneously switched on shifting of the flip-flops. The simultaneous switching causes a voltage drop (IR drop). The voltage drop leads to malfunction. To avoid the malfunction, one possible approach is to perform current countermeasures against electric current problems. The countermeasures against electric current problems include masking parts of the output of a generator of a pseudorandom number pattern or the shift data to be given to the scan chain. But the countermeasures against electric current problems seriously lower the fault detection rate. To avoid the decrease in the detection rate, the number of shift steps is required to be increased. The increase in the number of shift steps increases test time.

In addition, if logic BIST is used for self test, to avoid the problems of the countermeasures against electric current problems or to avoid the increase in the number of shift steps, excessive power supply design is required as a system. The excessive power supply design leads to higher cost and higher power consumption. The excessive power supply design leads to waste of battery for car appliances, portable devices, or the like.

Plus, if the logic BIST is used for self test, to avoid the problem of the countermeasures against electric current problems or to avoid the increase in the number of shift steps, the system is required to implement an arrangement. The arrangement indicates the arrangement for determining whether the logic BIST correctly detects a fault or not and the logic BIST circuit itself has no fault or not.

Certain embodiments provide a semiconductor integrated circuit, comprising: a logic circuit including plural combination circuits and plural first flip-flops; plural selectors for respective first flip-flops configured to switch between first paths from the combination circuits and second paths from previous stage flip-flops of the first flip-flops; plural scan chains in the logic circuit, each of the scan chains configured to have the second path activated based on selection by the selectors; a pattern generator configured to generate patterns for test for the scan chains; a test control circuit configured to drive the pattern generator and cause the plural selectors to switch, the test control circuit performing self test by a result of response from the scan chains; and plural setting terminals configured to set logic values individually in a combination of a part of second flip-flops, the second flip-flops being representative of a logic pattern and are of the first flip-flops in the logic circuit tested by the test control circuit.

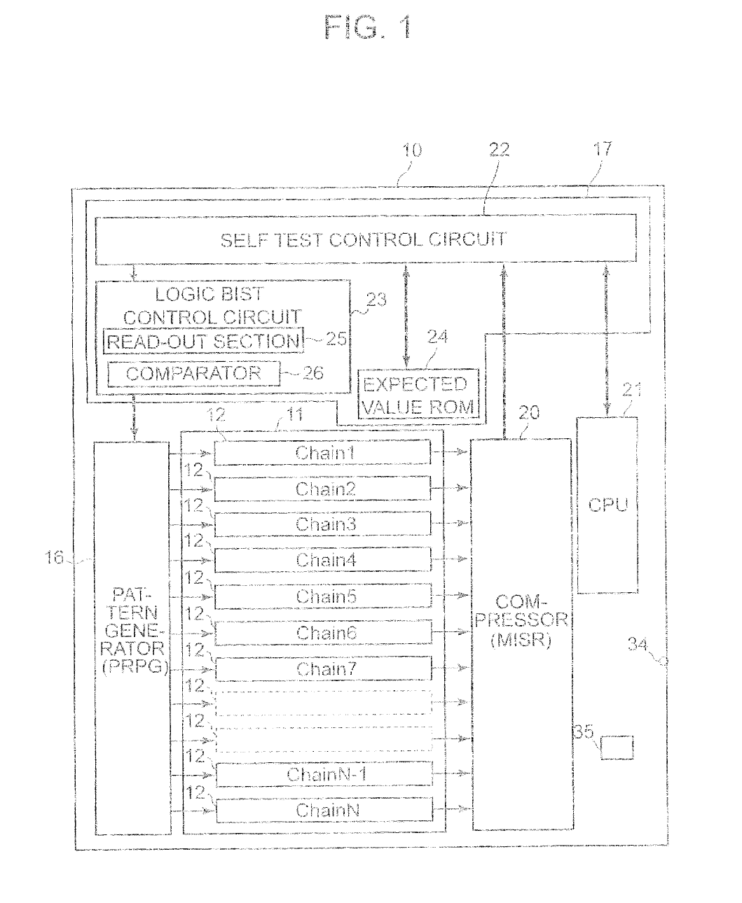

In the followings, a semiconductor integrated circuit and a method for self test of the semiconductor integrated circuit according to embodiments will be described with reference to FIGS. 1 to 11K. In the drawings, the same reference numeral is assigned to the same part, and a duplicated description will not be repeated.

### First Embodiment

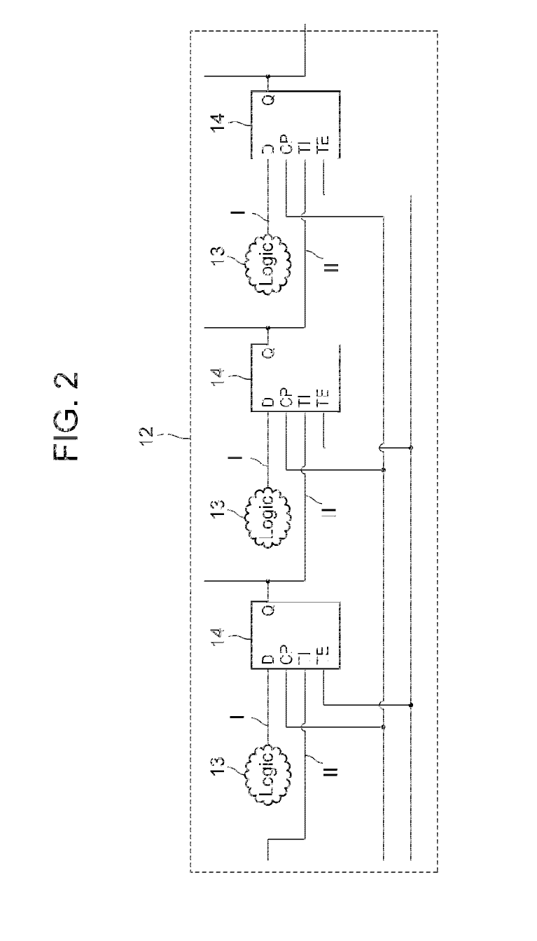

FIG. 1 is a circuit block diagram of a semiconductor integrated circuit according to a first embodiment. A configuration of a logic BIST for mass-production test is shown. FIG. 2 shows an excerpt part of a scan chain.

The semiconductor integrated circuit according to the embodiment is the whole of an IC 10 including a logic circuit 11.

The IC 10 is equipped with the logic circuit 11 as a circuit block under test and a plurality of scan chains (shift chains) 12 in the logic circuit 11.

The IC 10 repeatedly shifts the test data into the scan chains 12, actually operates the logic circuit 11, shifts data out, and accumulates the output of result. After shifting in and shifting out plural times, the IC 10 compares the accumulated data with an expected value. The IC 10 determines whether the logic circuit 11 has a fault or not.

The logic circuit 11 has a plurality of FFs (flip-flops) 14. The FFs 14 have a plurality of combination circuits and two input systems. The scan chain 12 is formed in a cascade arrangement of the FFs.

Each scan chain 12 is provided to be grouped based on, for example, clock frequencies.

FIG. 2 is a circuit block diagram of one scan chain 12. The already described reference numerals represent the same elements.

Each scan chain 12 is scannable. The scan chain 12 is formed in the originally existing FFs 14 and combination circuits 13 (written as “Logic”).

The scan chains 12 are generated after the FFs 14 are generated. A software tool generates the scan chains 12, depending on the connectional relationship between the FFs 14. Each combination circuit 13 outputs a unique logic value depending only on present inputs.

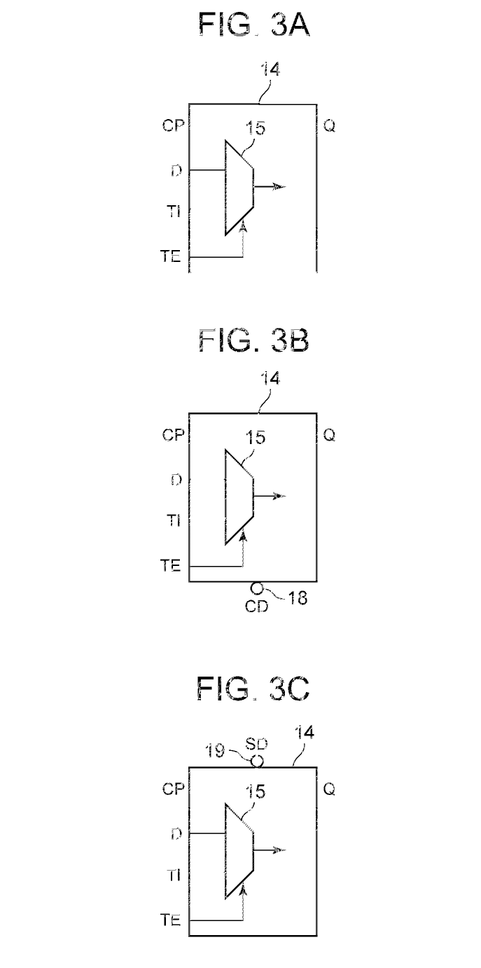

The FFs 14 hold state values which are previously set. FIG. 3A is a diagram showing a structural example of the FF 14. The FF 14 includes a selector 15.

The FF 14 has an input terminal D for a signal coming through the combination circuit 13, an input terminal TI for a test signal, and a clock terminal CP for a clock signal. The FF 14 has a control terminal TE to which a switching control signal Shift En (shift enable) is input, and an output terminal Q for the state value of the FF 14.

The selectors 15 in FIG. 2 switch between first paths (represented by Is) and second paths (represented by IIs) in respective FFs 14. The first paths are for taking-in data from the combination circuits 13. The second paths are for taking-in data from the previous stage FFs 14. The first paths are connected to respective input terminals D (normal). The second paths are connected to respective input terminals TI (shift data).

As shown in FIG. 2 and FIG. 3A, the scan chain 12 has the second paths II, which are activated by selection made by the selector 15. By activation of the second paths II, the scan chain 12 forms a shift register.

Further, FIG. 3B and FIG. 3C are diagrams showing structural examples of other types of FF 14. In the drawings, the already described reference numerals represent the same elements.

Besides the FF 14 in FIG. 3A, the IC 10 includes resettable FFs 14 and presettable FFs 14 in the logic circuit 11.

The resettable FF 14 in FIG. 3B has a Reset terminal 18 (CD) for setting the state value of the FF 14 to be 0 (Low). The presettable FF 14 in FIG. 3C has a Preset terminal 19 (SD) for setting the state value of the FF 14 to be 1 (High).

The Reset terminal 18 and the Preset terminal 19 are terminals both for setting logic values individually in a part of FFs 14 which are a combination of FFs 14 representing a logic pattern.

For instance, the Preset terminal 19, the Reset terminal 18, and the Preset terminal 19 set the logic values “1”, “0”, and “1” individually in three of the FFs 14. The three FFs 14 are the combination of flip-flops (the part of second flip-flops) representing the three bit logic pattern “101”.

In the description cited below, the part of FFs 14, each of which is resettable/presettable (resettable or presettable), are sometimes referred to as resettable/presettable FFs 14.

The number of the resettable/presettable FFs 14 is equal to or less than the number of all the FFs 14.

Further, in FIG. 1, the IC 10 includes a pattern generator 16 and a test control circuit 17.

The pattern generator 16 is a pseudorandom number generator for generating patterns for test to be given to the scan chains 12. The pattern generator 16 generates a random number pattern such as a pseudorandom pattern.

The pattern generator 16 generates test data by a linear feedback shift register (LFSR) or a cellular automaton (CA).

The test control circuit 17 is a controller. The test control circuit 17 controls the drive of the pattern generator 16 and the switching of the selector 15.

The test control circuit 17 performs self test, based on the result of response from the scan chains 12 by an actual operation of the logic circuit 11. The test control circuit 17 identifies the location of a fault in the logic circuit 11 based on the result of the diagnosis.

The test control circuit 17 includes a self test control circuit 22, an expected value ROM (Read Only Memory) (storing section) 24, and a logic BIST control circuit 23.

The self test control circuit 22 performs a procedure of self test. The self test control circuit 22 is activated by a CPU 21 upon power-on.

The expected value ROM 24 stores an expected value for a random number pattern from the pattern generator 16 in advance.

The logic BIST control circuit 23 supplies a scan clock frequency to each of the scan chains 12. The scan clock frequency is obtained by a frequency which is divided from the system clock frequency.

The logic BIST control circuit 23 notifies the selector 15 (or the FF 14) of a signal for switching paths as shown in FIG. 3A.

The logic BIST control circuit 23 inputs the active Shift En in the control terminal TE as shown in FIG. 2. By the input, the logic BIST control circuit 23 causes each of the FFs 14 to select an input terminal TI (shift data) path associated with the second path II. The input terminal TI is connected to the Q output of the corresponding chain previous stage FF 14.

The logic BIST control circuit 23 inputs the non-active Shift En in the control terminal TE. By the input of the Shift En, the logic BIST control circuit 23 causes each of the FFs 14 to select a D (normal) path of the first path I.

The logic BIST control circuit 23 inputs a control signal which is not synchronized with the system clock in each of the resettable/presettable FFs 14 of FIG. 3B and FIG. 3C. The logic BIST control circuit 23 resets (to set value ‘0’) or presets (to set value ‘1’) the resettable/presettable FFs 14 at an arbitrary timing.

The logic BIST control circuit 23 of FIG. 1 further includes a read-out section 25 and a comparator 26.

The read-out section 25 reads out data streams of plural systems. The data streams of systems are output from the scan chains 12 with respect to the input of the random number pattern for test. The random number pattern has a code length equal to the number of shift steps of any one of the scan chains 12.

The comparator 26 compares a data stream obtained through compression by a compression section 20 with the expected value in the expected value ROM 24.

The IC 10 of FIG. 1 further includes the compressor 20 and the CPU (central processing unit) 21.

The IC 10 disposes the compressor 20 on the output side of the scan chains 12. The compressor 20 feeds compressed data to the test control circuit 17. The compressor 20 compresses each of the data streams of the systems, the number of which data streams is equal to the number of the scan chains 12.

The compressor 20 includes the purpose of reducing the amount of data by compression instead of testing all the outputs one by one. By using a small-scale circuit, the compressor 20 causes the process time to be reduced.

The compressor 20 is an MISR (a multi-input shift register). The CPU 21 inputs a control command in the test control circuit 17 by using another ROM and RAM (random access memory).

The IC 10 is equipped with a terminal 34 for inputting a signal and an oscillator 35 such as a PLL (phase locked loop) for a high-speed clock signal.

In the method for self test according to the present invention, the test control circuit 17 shifts the random number patterns in the scan chains 12. The test control circuit 17 sets 0 or 1 in the individual resettable/presettable FFs 14 with the Reset terminals 18 and the Preset terminals 19.

In addition, in the method, test control circuit 17 causes the logic circuit 11 to perform an actual operation. The test control circuit 17 checks whether the operation is normal, based on the data shifted out from the scan chains 12 and the expected value data in the expected value ROM 24.

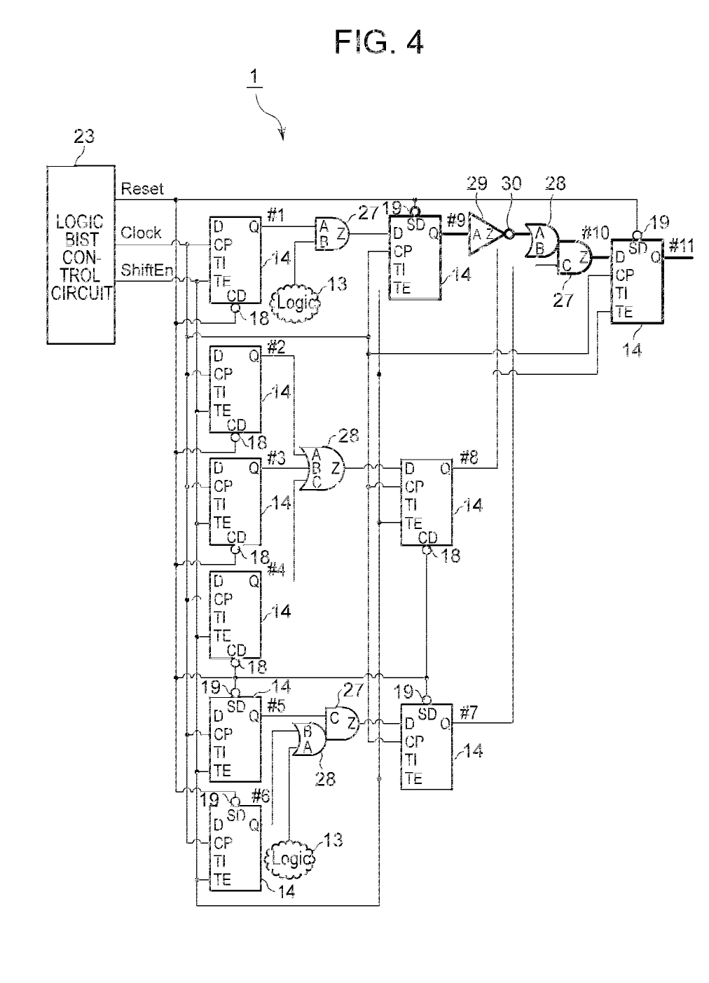

FIG. 4 is a circuit diagram showing a specific example of the semiconductor integrated circuit according to the embodiment. A self test circuit 1 is a specific example showing a part of the IC 10 of FIG. 1. The already described reference numerals represent the same elements.

The symbols #1 to #11 in the drawing indicate node names or signal names. To surely set a value in the FFs 14 to output #7, #8, #9, and #11, the FFs 14 for outputting #1 to #6 are connected on the previous stage of such FFs 14.

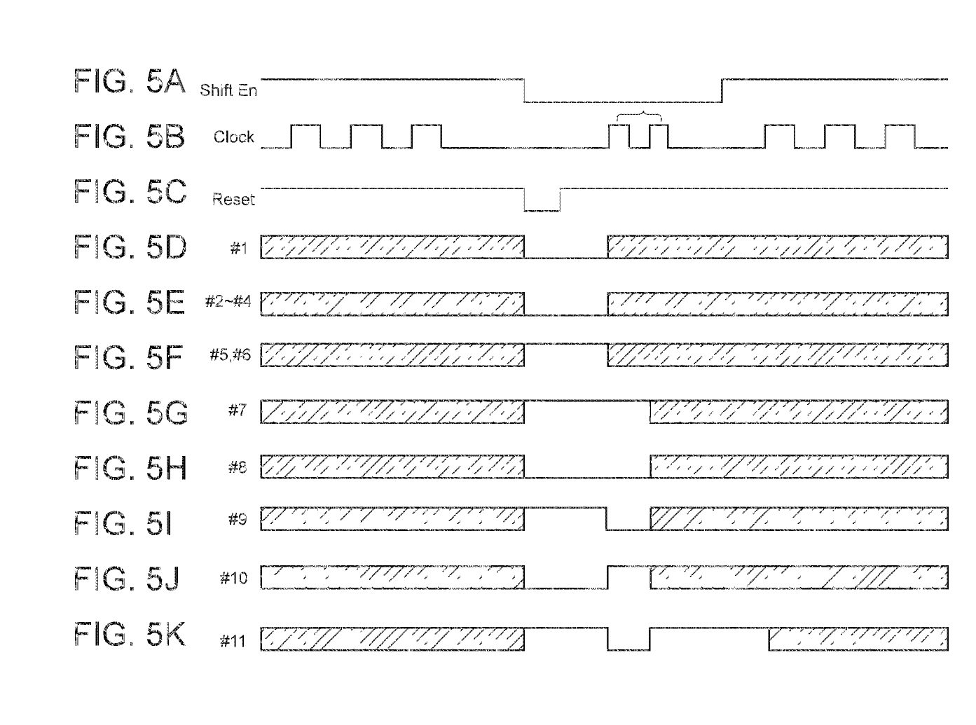

FIGS. 5A to 5K are timing charts of the operation of the self test performed by the logic BIST control circuit 23 of the semiconductor integrated circuit according to the present embodiment.

FIG. 5A is a timing chart (the signal name is Shift En) for switching the paths of the FFs 14.

FIG. 5B is a timing chart showing the clock. The clock is a system clock of the LSI. During the normal shift, the slow-speed clock is applied to the self test circuit 1 from the terminal 34. At the time of the launch and the capture, the self test circuit 1 operates at an actual operation speed. That is, the self test circuit 1 operates at an actual operation frequency by using the high-speed clock from the oscillator 35.

FIG. 5C is a timing chart showing the logic of the drive signal supplied to the resettable/presettable FFs 14.

FIGS. 5D to 5K are timing chart showing the voltage values at the nodes #1 to #11. The shaded areas represent “don't-care (no care needed).”

Next, the action of the thus configured self test circuit 1 will be described with reference to FIG. 4 and FIGS. 5A to 5K.

With reference to FIG. 4, the test is intended to cause the logic BIST control circuit 23 to detect a fault. The fault indicates a failure with respect to whether the logic is transferred to #11 or not, if the FF 14 captures data on the heavy-lined path. By the capturing, the self test circuit 1 is tested on whether the logic of #11 is changed from L to H or not. The capturing means, in particular, the capturing which is done at an actual operation speed at the path where the logic of #9 is changed from H to L and at the path where the logic of #10 is changed from L to H.

Here, the capturing indicates that the FFs 14 take in the signal values from the logic circuit 11 through the input terminals D. The heavy-lined part is configured with an FF 14 for outputting #9, a buffer 29, an inverter 30, an OR gate 28, an AND gate 27, and the FF 14 for outputting #11.

The FFs 14 to which the symbols #1 to #11 are assigned and the AND gate 27 which outputs #10 are selected in advance during a design stage. After generating the scan chains 12, the software tool searches the FFs 14 having the symbols #1 to #11 and the AND gates 27 outputting the logic #10 in the logic circuit 11. The FFs 14 and the AND gates 27 are identified. A plurality of functions are executed by, for instance, the self test control circuit 22. The functions include: holding information of the FFs 14 to be selected during the design stage; searching the FFs 14 and the AND gates 27 by using the tool; and identifying the FFs 14 and the AND gates 27.

For the purpose of causing the logic BIST control circuit 23 to detect a fault, in the self test circuit 1 according to the first embodiment, a Reset signal shown in FIG. 4 is connected to the asynchronous Reset terminals 18 or the asynchronous Preset terminals 19 of the FFs 14. As shown in the timing charts in FIGS. 5A to 5K, the logic BIST control circuit 23 keeps asserting the Reset signal, in the period after the completion of the shift operation and before the generation of a Launch Clock and a Capture Clock. The Capture clocks are given a mark in FIG. 5B. In the example of the drawing, “to be asserted” means “to be active if L.” At the time when the Launch Clock and the Capture Clock are generated, the logic BIST control circuit 23 shifts the Reset signal to non-active.

With this arrangement, the above-described desired logic transition can be executed at the time of the capture. The self test circuit 1 is operative to surely perform the test by using the logic BIST with intended logic patterns at an actual operation speed.

Before describing in detail below, a logic control procedure will be described. In general, the logic BIST control circuit 23 performs the procedure by switching between three states. The logic BIST control circuit 23 switches the state of the self test circuit 1 to: (1) a shift state (Shift En is high) first; (2) a capture state (Shift En is low); and (3) the shift state (Shift En is high) again.

(1) During the first shift state, plural shift registers are made up of FFs 14 in the self test circuit 1. The self test circuit 1 shifts-in data to the shift registers. Values are set in the FFs 14 constituting the shift registers.

(2) Next, during the capture state, the values set in the FFs 14 pass through the combination circuits 13. The values from the combination circuits 13 are taken into the FFs 14 on the following stages.

(3) Then, the self test circuit 1 is set back to the shift state from the capture state.

It is noted that for the purpose of testing the logic transition of aforesaid #9, #10, and #11, the logic BIST control circuit 23 pays attention to the result of the waveforms during the capture state (2). A detailed description will be made below.

First, in the shift state in FIG. 5A, the logic BIST control circuit 23 shifts the data into the self test circuit 1.

As shown in FIG. 5B, during the shift in, the data are shifted between the FFs 14 in the circuit of FIG. 4 by the clock.

The Reset signal in FIG. 5C switches the state of the self test circuit 1 into the capture state. In response to the Reset signal, #9, #10, and #11 turn 1, 0, and 1, respectively as shown in FIGS. 5I to 5K.

As shown in FIG. 5B, the logic BIST control circuit 23 generates two clock signals.

The first clock represents the Launch Clock for causing transition of state. The Launch Clock causes the internal values of the FFs 14 outputting #9, #10, #11 to transit to “0”, “1”, “0” as shown in FIGS. 5I to 5K.

The second clock represents the Capture Clock for taking in the result which is the result to be settled after the transition. Upon the Capture Clock, the result of #11 is taken into the next stage FF 14 as shown in FIGS. 5J and 5K.

Next, as shown in FIG. 5A, the state is switched from the capture state to the shift state. During the shift state, the logic BIST control circuit 23 scans out the data from the resettable/presettable FFs 14 through the shift registers.

Next, back to FIG. 1, the read-out section 25 of the logic BIST control circuit 23 takes the data therein. The comparator 26 compares the thus taken-in data with the expected value stored in the expected value ROM 24. With respect to an arbitrary number of FFs 14, the self test circuit is operable of making a determination on whether the FFs 14 are good or not.

In addition, the logic BIST control circuit 23 detects whether the circuit has a fault, based on the verification of true or false between the two data. The fault indicates a delay fault.

If a fault is created, data in the previous stage FF 14 does not reach the next stage FF 14 at the rising or falling edge of the clock. Depending on the result of the comparison, whether some data have not yet arrived or not is detected. The IC 10 becomes determinable whether the heavy-lined part of FIG. 4 has a fault or not.

Here, the logic of the part represented by “Logic” in FIG. 4 indicates don't-care. The terminals D and TI which are of the FFs 14 and not shown in the drawing also can be don't-care. Further, the logic BIST control circuit 23 has only to perform the operation of reset in FIG. 5C at least once at an arbitrary time in plural times. Single reset is sufficient in the test by logic BIST which repeats a pair of shift and capture plural times.

As described above, since the part of FFs 14 are resettable/presettable, a desired logic transition such as a 3-bit pattern “101” can be obtained at the time of capture.

With the self test circuit 1, the logic of #9 and the logic of #10 on the heavy line are captured at an actual operation speed after shifting in the data. The self test circuit 1 becomes testable on whether the logic transition of #11 is surely transferred or not.

The problems with the related art will be compared with the example of the first embodiment. The semiconductor integrated circuit of the related art has no Reset signal. At the time when the Reset signal gets asserted according to the first embodiment, a logic formed by a bit pattern having the same length as the length of the chain is required to be set in the FFs of the related art. Since the shift data is random, the related art is not able to assure that a shift pattern which executes the logic can surely be obtained. Suppose that the whole elements in the circuit to be shift-scanned is already generated at the early development stage. If whole elements are generated, the scan chains themselves are sometimes modified by the progress of the development stage. Or even if the circuit logic to be shift-scanned is not modified, the operation of the circuit is not assured. Even in the case that the bit number of the pattern generator 16 is increased, the operation of the circuit is not necessarily assured.

With the semiconductor integrated circuit according to the present embodiment, a desired logic pattern can be set by using asynchronous resettable/presettable FFs 14. A fault in a specific pattern which is hardly detected by logic BIST of the related art is easily detected.

The test pattern for a specific part of the FFs 14 cannot be generated in a short time by the pattern generator 16. If the pattern generator 16 keeps outputting forever, the semiconductor integrated circuit according to the present embodiment can be said that such input pattern can be generated. With the semiconductor integrated circuit according to the present embodiment, a part of FFs 14 can previously be set to a logic such as “1”, “0”, “1”. With the logic previously having been set, a normal change of logic in a circuit at a specific part of the LSI and the transmission of the logic can be tested. The IC 10 forcibly resets the inputs for the FFs 14 in the block under test, and observes the outputs with respect to the inputs in a predetermined pattern. The forcible reset and the observation of the outputs make the test possible without waiting for the inputs from the pattern generator 16. The semiconductor integrated circuit according to the present embodiment becomes testable on whether an output pattern from a partial circuit is normal or not.

In addition, with the semiconductor integrated circuit according to the present embodiment, test can be performed without any test points for observation being put in. Because of no test points, the detection accuracy of a delay fault can be improved. With the semiconductor integrated circuit according to the present embodiment, the semiconductor integrated circuit becomes operable of avoiding to put in test points. Because of no test points being put in, the detection accuracy of a delay fault can be more improved than the related art.

### Second Embodiment

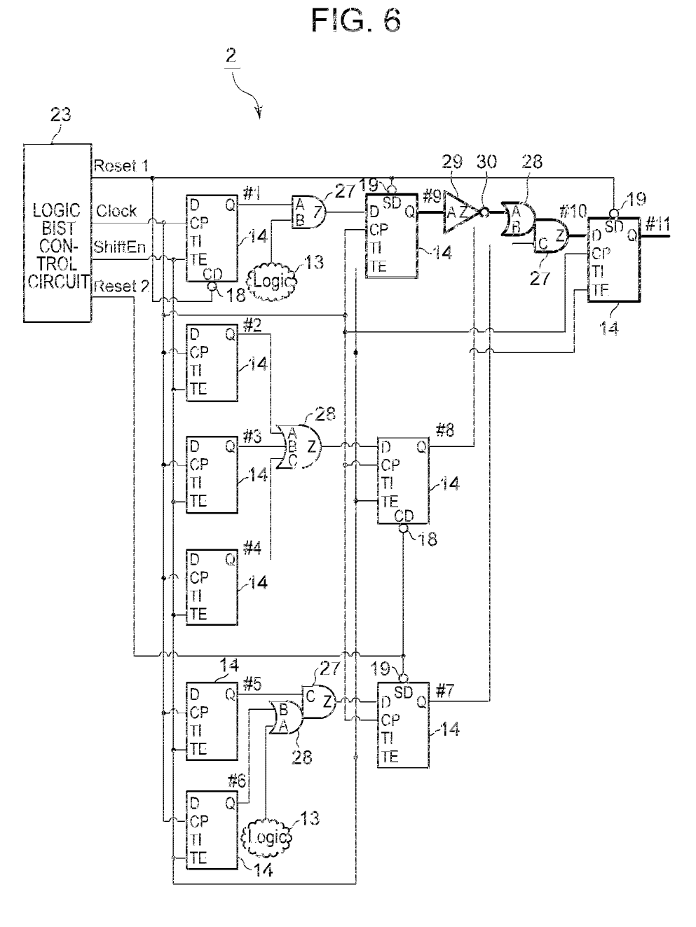

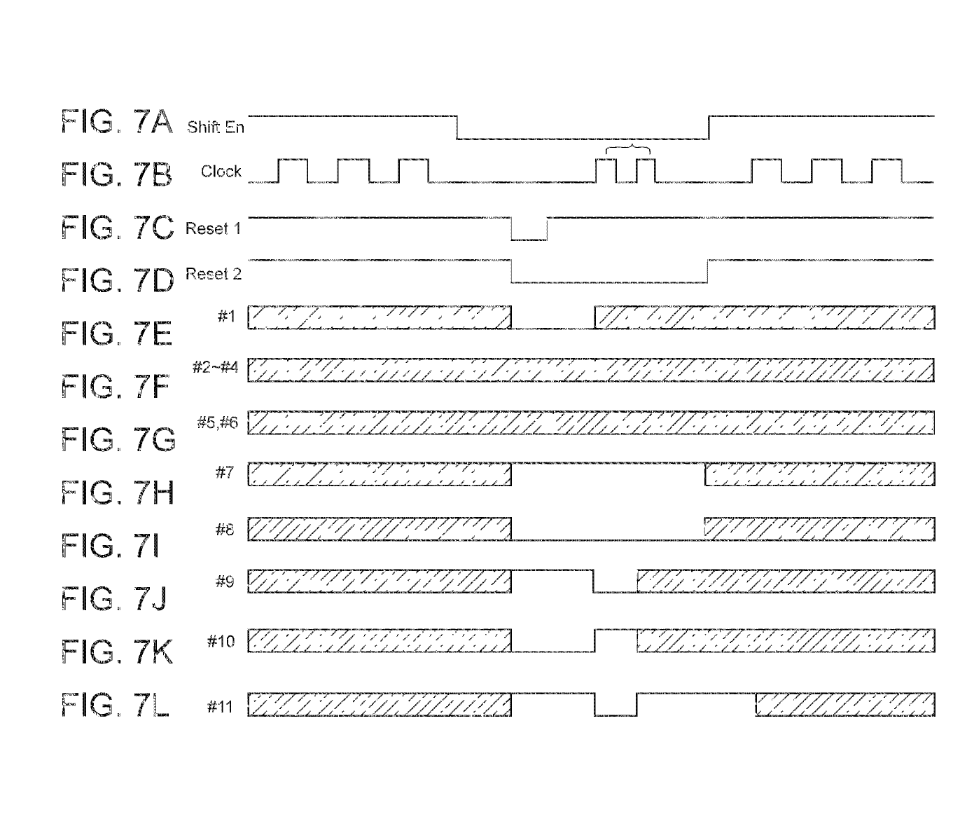

In the first embodiment, the number of the Reset signal is one, but the number may be more than one. A circuit configuration and timing charts of the second embodiment are shown in FIG. 6 and FIGS. 7A to 7L, respectively.

FIG. 6 is a circuit diagram showing a specific example of a semiconductor integrated circuit according to the second embodiment. A self test circuit 2 is a specific example showing a part of the IC 10 (FIG. 1). The already described reference numerals represent the same elements.

Any one of the following FF 14 is the resettable/presettable part of FFs 14: an FF 14 for outputting #1; an FF 14 for outputting #7; an FF 14 for outputting #8; an FF 14 for outputting #9; and an FF 14 for outputting #11.

The semiconductor integrated circuit according to the second embodiment is different from the semiconductor integrated circuit according to the first embodiment in that, the semiconductor integrated circuit by the second embodiment has a Reset 2 (a Reset signal 2) separated from a Reset 1 (a Reset signal 1), and reset control of FFs 14 for outputting #2 to #6 is unnecessary.

The Reset 1 and the Reset 2, which are for both reset and preset, are distributed to two groups, respectively.

As a first group, the FFs 14 for outputting #1, #9, and #11 receive the Reset signal Reset 1 from the logic BIST control circuit 23 through a Reset terminal 18, a Preset terminal 19, and a Preset terminal 19, respectively.

As a second group, the FFs 14 for outputting #7 and #8 receive the Reset signal Reset 2 through the Reset terminal 18 and the Preset terminal 19.

Regarding components not shown in FIG. 6, the semiconductor integrated circuit according to the present embodiment has substantially the same components as the semiconductor integrated circuit according to the first embodiment. A duplicated description of the components will not be repeated.

FIGS. 7A to 7L are timing charts of an operation of self test performed by a logic BIST control circuit 23 of the semiconductor integrated circuit according to the present embodiment.

FIG. 7C is a timing chart showing a logic of the first Reset signal Reset 1.

FIG. 7D is a timing chart showing a logic of the second Reset signal Reset 2.

FIGS. 7E to 7L are timing charts each showing a voltage of each of nodes #1 to #11. The shaded areas represent don't-care.

Next, action of the thus configured self test circuit 2 will be described with reference to FIG. 6 and FIG. 7.

With reference to FIG. 6, the test is intended to cause the logic BIST control circuit 23 to detect a fault (the same as in the first embodiment). The fault indicates a failure with respect to whether the logic transition is transferred to #11 or not, if the FF 14 captures the heavy-lined path (the FF 14 for outputting #9, a buffer 29, an inverter 30, an OR gate 28, an AND gate 27, and the FF 14 for outputting #11). By the capturing, the self test circuit 2 is operable to test whether the logic of #11 changes from L to H. The capturing means, in particular, the capturing which is done at an actual operation speed at the path where logic of #9 is changed from H to L and at the path where the logic of #10 is changed from L to H.

The difference between the first and the second embodiments is that the path for the Reset signal for the FFs 14 for outputting #7 and #8 is separated from the path for the Reset signal for the FFs 14 for outputting #1 and #9. The semiconductor integrated circuit of the second embodiment has also difference from one of the first embodiment in that reset control for the FFs 14 for outputting #2 to #6 is unnecessary. In the same way as in FIG. 4, #2 to #6 represent don't-care.

In the second embodiment, by keeping the logic of #7 and #8 at a constant value during the capture period, the self test circuit 2 is operable to capture a similar logic transition as the transition in the first embodiment and to detect a fault at an actual operation speed.

First, as shown in FIG. 7A, in a first shift state, the logic BIST control circuit 23 shifts data into the self test circuit 2.

As in FIGS. 7C and 7D, the logic BIST control circuit 23 inputs the Reset 1 and the Reset 2 into two groups of flip-flops.

As in FIGS. 7H and 7I, the FFs 14 for outputting #7 and #8 are preset or reset by the Reset 2, respectively.

As in FIGS. 7E and 7J, the FFs 14 for outputting #1 and #9 are reset or preset by the Reset 1, respectively.

The logic BIST control circuit 23 causes #7 and #8 to hold constant logic values until the end of the capture period as shown in FIGS. 7H and 7I. Until the generation of a Launch Clock and a Capture Clock, the logic BIST control circuit 23 keeps asserting the Reset 2 as shown in FIG. 7D.

In response to the Launch Clock, #9, #10, and #11 change to 0, 1, and 0, respectively. In response to the Capture Clock, the result of #11 is taken in (see FIGS. 7J to 7L).

After scanning out the data from the FF 14 for outputting #11, the self test circuit 2 compares the captured data and the expected value data with each other.

As described above, the self test circuit 2 becomes operable to capture the logic transition and detect a fault at an actual operation speed in the same way as in the first embodiment.

With the semiconductor integrated circuit according to the present embodiment, the semiconductor integrated circuit becomes operative to minimize the number of the presettable/resettable FFs 14.

### Third Embodiment

In the above-described embodiments, the Reset terminals 18 reset FFs 14, and the Preset terminals 19 preset the FFs 14 asynchronously to the clock. A semiconductor integrated circuit according to the third embodiment may reset and preset synchronously with the clock by using other logic circuits provided in the input path for the FFs 14.

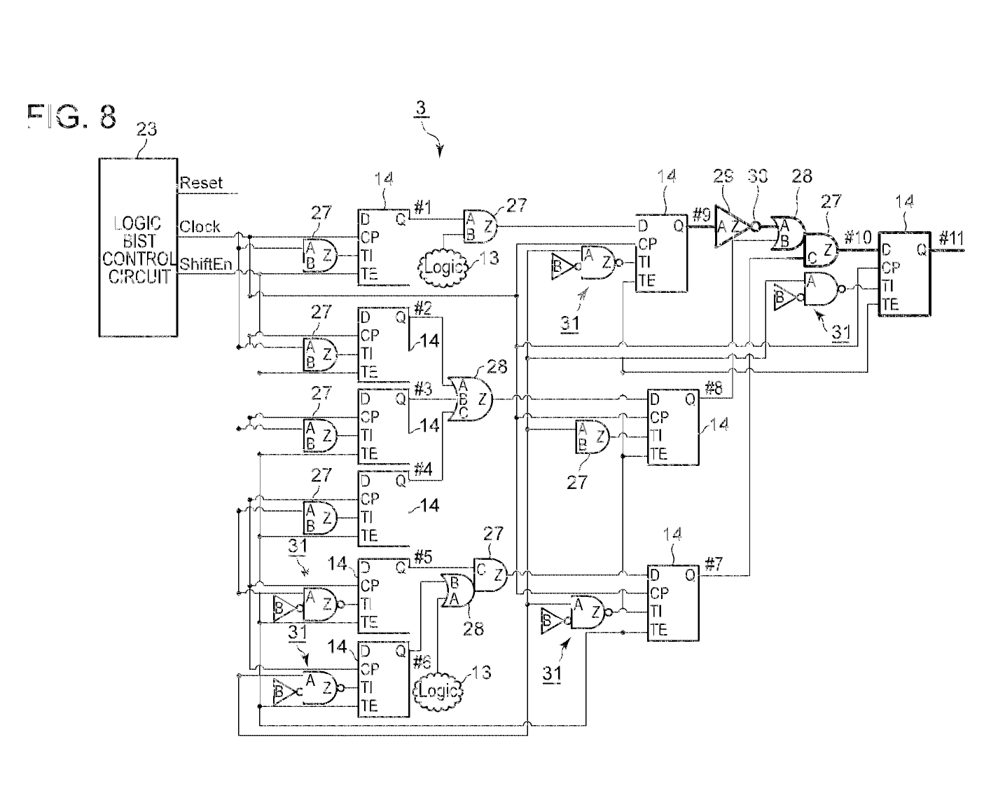

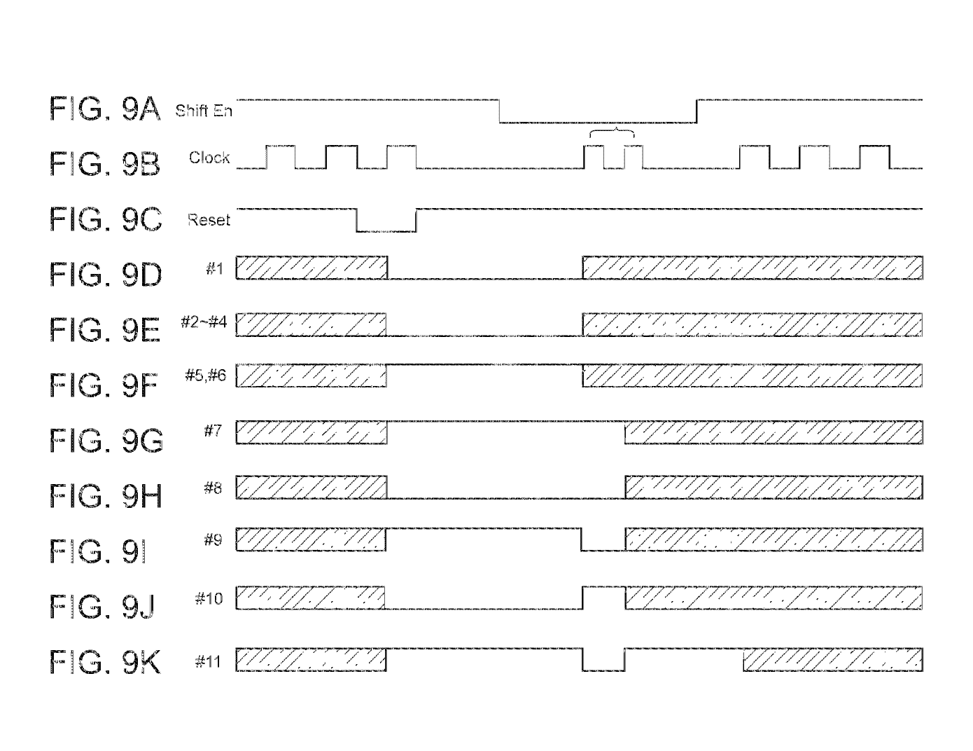

A circuit configuration and timing charts of the third embodiment is shown in FIG. 8 and FIGS. 9A to 9K, respectively.

FIG. 8 is a circuit diagram showing a specific example of the semiconductor integrated circuit according to the third embodiment. A self test circuit 3 is a specific example showing a part of the IC 10 of FIG. 1. The already described reference numerals represent the same elements.

AND gates 27 (other logic circuits) are connected to input terminals TI (input paths), to which shift data are fed, of the FFs 14 for outputting #1 to #4, and #8.

The gate circuits 31 (other logic circuits) are connected to respective input terminals TI (input paths), to which shift data are fed, of the FFs 14 for outputting #5, #6, #7, #9, and #11.

The self test circuit 3 disposes the AND gates 27 and the gate circuits 31 on the input terminals TI of a part of FFs 14 for outputting #1 to #11. The AND gates 27 and the gate circuits 31 are setting terminals for individually setting logic value in respective FFs 14 synchronously with a system clock.

The logic BIST control circuit 23 sets values in the AND gates 27 and the gate circuits 31 at the final stage of shift-in operation of a random number pattern by the scan chains 12.

Regarding components not shown in FIG. 8, the semiconductor integrated circuit according to the present embodiment has substantially the same components as the semiconductor integrated circuit according to the first embodiment. A duplicated description of the components will not be repeated.

FIGS. 9A to 9K are timing charts of an operation of self test performed by the logic BIST control circuit 23 of the semiconductor integrated circuit according to the present embodiment.

FIGS. 9A to 9C are the same as the examples of FIGS. 5A to 5C. FIGS. 9D to 9K are timing charts showing voltages at nodes #1 to #11. The shaded areas represent don't-care.

The action of the self test circuit 3 configured as described above will be described with reference to FIG. 8 and FIGS. 9A to 9K.

With reference to FIG. 8, the test is intended to cause the logic BIST control circuit 23 to detect a fault (the same as in the first embodiment and the second embodiment). The fault indicates a failure with respect to whether the logic transition is transferred to #11 or not, if the FF 14 captures data on the heavy-lined path (the FF 14 for outputting #9, a buffer 29, an inverter 30, an OR gate 28, an AND gate 27, and the FF 14 for outputting #11). By the capturing, the self test circuit 3 is operable to test whether the logic of #11 is changed from L to H. The capturing means the capturing which is done at an actual operation speed at the path where logic of #9 is changed from H to L and at the path where the logic of #10 is changed from L to H.

The difference between the third and the first and the second embodiments is that, in the third embodiment, the FFs 14 are not asynchronous reset/preset type, and the self test circuit 3 adds combination logic circuits to the TI (shift data input) paths. By connecting the logic circuits to the FFs 14, the Reset/preset signals are input to the FFs 14. In other words, the third embodiment is different from the first embodiment in that the flip-flops are replaced with the synchronous FFs 14. The “synchronism” means that the timing when the FFs 14 are reset/preset is in synchronism with the clock.

As shown in FIG. 9B, the self test circuit 3 controls to turn the Reset signal to active (L) if the last clock in the shift cycle (the period of the shift state) rises. By the control, the self test circuit 3 is able to execute to set, in the same way as the first embodiment, desired logics in all of the FFs 14 for outputting #1 to #11 before a Launch Clock and a Capture Clock start.

By setting logic values in all of the FFs 14 before the start of the Capture Clock, the self test circuit 3 is operable to obtain a desired logic transition such as the above-described 3-bit pattern “1”, “0”, “1” at the time of the capture. The self test circuit 3 is operable to perform the test by logic BIST with a logic pattern such as a 3-bit pattern at an actual operation speed.

A detailed description will be made. First, as shown in FIG. 9A, the self test circuit 3 takes data into the FFs 14 from the input terminals TI at the first shift state (Shift En is high).

As shown in FIG. 9C, the logic BIST control circuit 23 asserts (L) the Reset signal.

When the Reset signal is asserted (L), the rising edge of the clock in FIG. 9B is applied to the FFs.

As shown in FIGS. 9D to 9K, the self test circuit 3 reset or preset each of the input paths to TI (shift data input path) of the FFs 14 for outputting #1 to #11. By the other logic circuits provided in the shift data input paths, the self test circuit 3 sets #5, #6, #7, #9, and #11 to “1”, respectively.

In other words, at the time of inputting the last clock of the shift cycle and on the ending stage of shift, the self test circuit 3 forcibly sets constant values in the other logic circuits (the AND gates 27 and the gate circuits 31).

Next, with reference to FIG. 9A, the self test circuit 3 changes the state from the shift state to the capture state (Shift En is low).

As shown in FIGS. 9I to 9K, in the capture state, #9, #10, and #11 output by the FFs 14 change to 0, 1, 0 in response to the Launch Clock. The following Capture Clock causes the corresponding FF 14 to take in the result of #11. After the data are scanned out from the presettable FF 14 for outputting #11, comparison is made.

The difference between the first and the second embodiments and the third embodiment is that, in this embodiment, the FFs 14 do not have to be asynchronous reset/preset types. On the flip side, the semiconductor integrated circuit by the third embodiment needs logic circuits such as AND gates in the TI paths. Suppose that a test point/points are put in the paths to improve a fault detection rate by logic BIST. The test point/points are to be put in with respect to a D input terminal of the FF 14 in the normal path. When the test point is put in, since the test point is put in the D terminal, the timing of the normal operation becomes tighter. In addition, there is a disadvantage that because of forcibly setting a logic on the normal path, test cannot be performed at an actual operation speed test.

The self test circuit 3 according to the third embodiment is equivalent to putting in a test point in a TI path. Putting in of AND gates 27 or the like does not disturb a normal path. At the time of normal shift, the AND gates 27 or the like do not transfer signals. In the self test circuit 3, the circuits operate in the same way as the normal operation. The Q output of the previous stage FF 14 is directly transferred to the input terminal TI of the next stage FF 14. The self test circuit 3 secures adequate timing margin. The self test circuit 3 is useful because of less concern about timing needed.

With the semiconductor integrated circuit according to the present embodiment, the semiconductor integrated circuit is operative to set the constant values on the final stage of the shift, and easily detect a fault due to a predetermined pattern. The detection accuracy of a delay fault can be improved.

In addition, the timing charts (FIGS. 9A to 9K) are also different from the timing charts (FIGS. 5A to 5K) of the first embodiment, and the timing at which values are set in the FFs 14 is distinctive.

In FIGS. 5A to 5K (the former), the timing to forcibly set values is after the completion of the shift and before the capture operation. In FIGS. 9A to 9K (the latter), the corresponding timing is at the time of the last shift.

Comparing FIG. 4 with FIG. 8, the way how to put values in existing circuits is different between FIG. 4 and FIG. 8. In FIG. 4 (the former), the values are put in the paths of asynchronous Reset or Preset of the FFs 14. In the self test circuit 3 (FIG. 8), the values are put in the TI (shift data) input paths. With the semiconductor integrated circuit according to the present embodiment, the example of FIG. 8 becomes superior to the example of FIG. 4 in terms of circuit scale.

### Fourth Embodiment

The semiconductor integrated circuits according to the first to third embodiments may check by using the semiconductor integrated circuit itself whether the function of self-fault diagnosis functions well.

The fourth embodiment is an example in which logic BIST is used for the self test of FIG. 1. The semiconductor integrated circuit according to the present embodiment has substantially the same components as the semiconductor integrated circuit according to the first embodiment shown as FIG. 1.

The semiconductor integrated circuit according to the present embodiment performs the fault diagnosis in a normal self test at the time when a predetermined numbers of shifts and captures are repeated by logic BIST. At that time, the logic BIST control circuit 23 makes a diagnosis of a fault by comparing the data compressed by the compressor 20 with the expected value.

However, for example, the comparator 26 (the comparator 26 cannot help being out of a target tested by logic BIST) sometimes has a fault. The comparator 26 can be thought to have a fault that the comparator 26 outputs “Comparison is OK” at all times. The fault means a “stuck-at fault” in which output remains fixed with variation of input. To detect the fault is also important.

The semiconductor integrated circuit of the present embodiment further performs the same fault diagnosis after the operation of a predetermined comparison. During the same fault diagnosis, the semiconductor integrated circuit asserts the Reset signal shown in the first through the third embodiments at a predetermined timing in the diagnosis. The semiconductor integrated circuit intentionally adds a fault therein. The semiconductor integrated circuit tests whether the comparison results indicates a judgment of NG (no good).

The semiconductor integrated circuit according to the fourth embodiment has substantially the same components as the semiconductor integrated circuits according to the first, second, and third embodiments. A duplicated description of the components will not be repeated.

The semiconductor integrated circuit according to the present embodiment which has the above-described configuration detects a fault in the comparator 26, which is not an element to be tested. After the comparison by the comparator 26, the semiconductor integrated circuit causes a fault during repeat of the same fault diagnosis as in the example of FIG. 4.

In repeating the shift and the capture, the semiconductor integrated circuit asserts the Reset signal (FIG. 5C, FIG. 7C, FIG. 7D, or FIG. 9C). The semiconductor integrated circuit purposely outputs fault data to the compressor 20 by asserting the Reset signal. The fault data are mixed into the normal data in the compressor 20. Whether the comparison result is determined to be a judgment of NG is tested by the comparator 26.

The semiconductor integrated circuit of the related art mixes fault data in in such a manner as using a specialized circuit or changing the number of shift.

The former (to install a specialized circuit) has a possibility that the specialized circuit itself has a fault. With the semiconductor integrated circuit of the present embodiment, the semiconductor integrated circuit is operable to perform a predetermined operation once by the Reset signal. The semiconductor integrated circuit according to the present embodiment operates the same Reset signal after a judgment of OK. The semiconductor integrated circuit is advantageous for its high reliability.

In addition, the latter (to change the number of shift) has many variety of parts in which fault data are mixed. The cases for fault data to be mixed in will be increased. The latter has a risk that a minor fault may be hidden. With the semiconductor integrated circuit of the present embodiment, since fault data are mixed into only a limited small area, the reliability is high.

In this embodiment, self test may be performed while intentionally generating fault data in elements different from the comparator 26 such as the read-out section 25, the logic BIST control circuit 23, and the self test control circuit 22, or the like.

With the semiconductor integrated circuit according to the present embodiment, the semiconductor integrated circuit becomes operable to easily check at the time of self test whether the embedded self test circuit such as the test control circuit 17 itself has a fault.

### Fifth Embodiment

In the above-described embodiments, the semiconductor integrated circuit according to embodiment may exclude the Reset terminal 18, the Preset terminal 19, the AND gate 27, or the FF 14 having a gate circuit 31 from the scan chain 12.

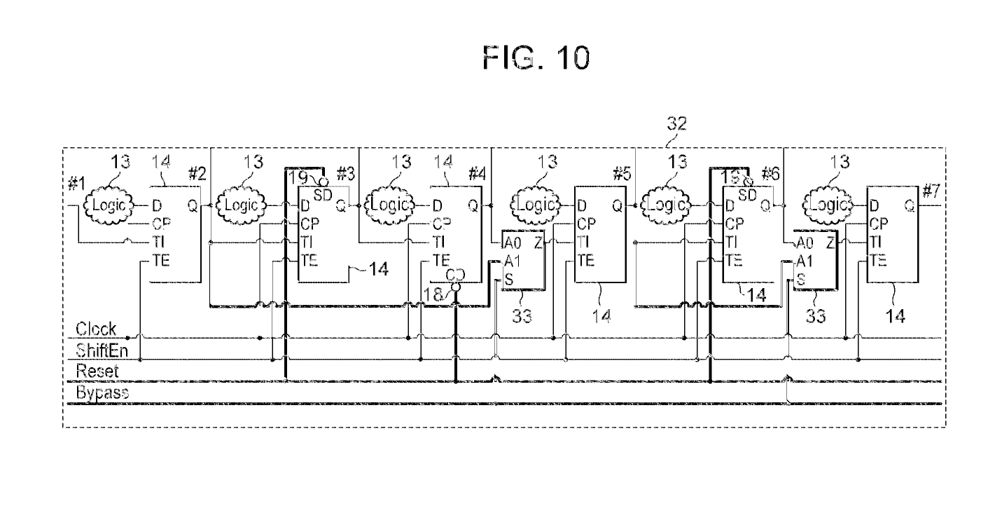

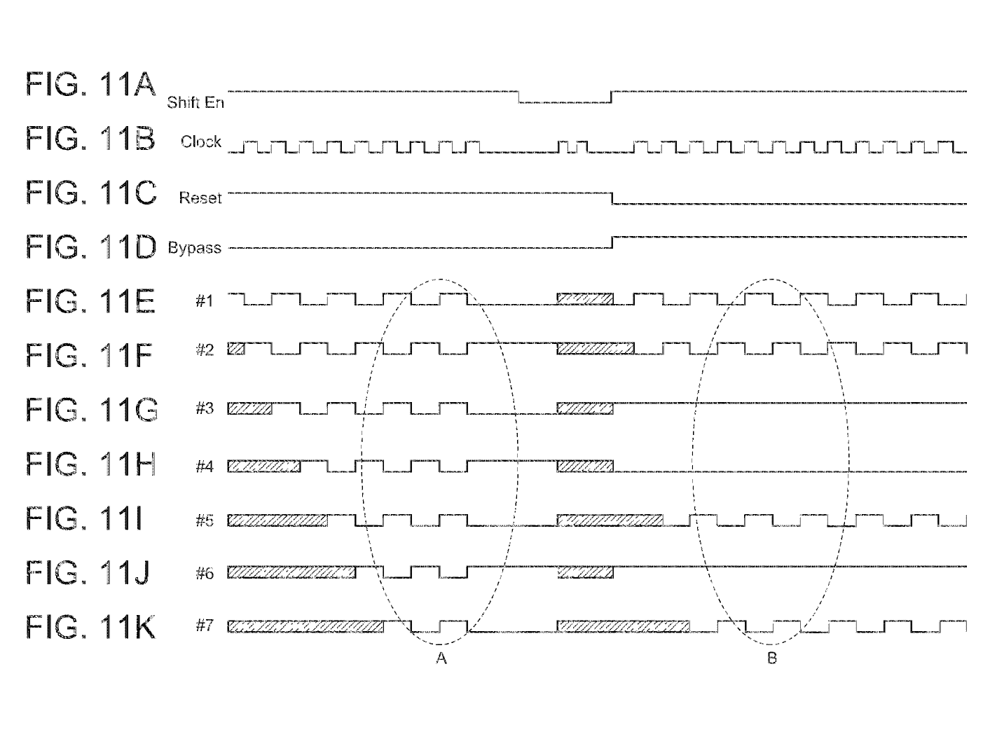

A circuit configuration of the semiconductor integrated circuit of the fifth embodiment is shown in FIG. 10. Timing charts with respect to the circuit are shown, respectively in FIG. 11.

FIG. 10 is a circuit diagram of a specific example of a semiconductor integrated circuit according to the fifth embodiment. The already described reference numerals represent the same elements. A self test circuit 32 represents a part of the IC 10 (FIG. 1).

The self test circuit 32 bypasses that the Q outputs of the previous stage FFs 14 are directly shifted into TI input paths.

In FIG. 10, each of the FFs 14 for outputting #3, #4, and #6 has a Reset terminal 18 and a Preset terminal 19. The FFs 14 are the asynchronously resettable/presettable part of FFs 14 as described in the first embodiment and the second embodiment.

The self test circuit 32 includes multiplexers (bypass section) 33 in respective TI input paths of the FFs 14 for outputting #5 and #7.

A first multiplexer 33 at the horizontal center of the drawing bypasses a shift path from the FFs 14 (the part of flip-flops) for outputting #3 and #4 to the FF 14 (the flip-flop different from the part of flip-flops) for outputting #5.

The first multiplexer 33 connects/inputs the data, to #5, from one of the FF 14 for outputting #4 and the FF 14 for outputting #2 which is before #4.

Similarly, a second multiplexer 33 bypasses a shift path from the FF 14 (the part of flip-flops) for outputting #6 to the FF 14 (the flip-flop different from the part of flip-flops) for outputting #7.

The second multiplexer 33 inputs/outputs the data, to #7, from one of the FF 14 for out putting #6 and the FF 14 for outputting #5 which is on the previous stage of #6.

Each multiplexer 33 has a first input terminal A0, a second input terminal A1, a terminal S for a bypass signal for switching bypass/non-bypass, and an output terminal Z.

The first multiplexer 33 changes shift paths and bypasses the presettable FF 14 for outputting #3 and the resettable FF 14 for outputting #4.

The second multiplexer 33 changes shift paths and bypasses the presettable FF 14 for outputting #6.

The logic BIST control circuit 23 controls to switch whether to bypass the shift path by the multiplexer 33 or not to bypass. The logic BIST control circuit 23 causes the multiplexer 33 to switch the shift path to the bypass side during the shift in of a random number pattern.

The logic BIST control circuit 23 may make the logic of the bypass signal and the logic of the Reset signal be constantly opposite to each other. The logic BIST control circuit 23 may switch the bypass signal and the Reset signal synchronously with each other.

The terminals S of the multiplexers 33 for the bypass signal are supplied with the bypass signal from the logic BIST control circuit 23.

A configuration may be made such that the bypass signal and the Reset signal are constantly opposite logic to each other, and the bypass paths may be selected by the multiplexers 33 with the inverted logic of the Reset signal instead of the bypass signal.

Regarding components not shown in FIG. 10, the self test circuit 32 has substantially the same components as the semiconductor integrated circuit according to the first, second, and third embodiments. A duplicated description of the components will not be repeated.

FIGS. 11A to 11K are timing charts of the operation of the self test performed by the logic BIST control circuit 23 of the semiconductor integrated circuit according to the present embodiment.

FIG. 11A and FIG. 11B is the same as the examples of FIG. 5A and FIG. 5B, respectively.

FIG. 11C is a timing chart showing a logic of a signal to the resettable/presettable FFs 14. FIG. 11D is a timing chart showing a logic of a bypass control signal.

FIGS. 11E to 11K are timing charts showing the voltages at the nodes #1 to #7. The shaded areas represent don't-care.

Next, the action of the thus configured self test circuit 32 will be described with reference to FIG. 10, FIGS. 11A to 11K.

In FIG. 10, the FFs 14 for outputting #3, #4, and #6 are asynchronous presettable FFs 14 used in the first and the second embodiments. A characteristic configuration of the present embodiment is that the multiplexer 33 is installed in the TI input path of each of the FFs 14 for outputting #5 and #7. The multiplexers 33 can switch the shift path to the shift path coming from the previous stage FF 14 instead of a normal shift path. The change of the shift path can bypass the presettable FF 14 by the multiplexer 33. The multiplexer 33 selects the bypass path, depending on the bypass signal (an inverted logic of the Reset signal may be possible) from the logic BIST control circuit 23.

A detailed description will be made below. As shown in FIG. 11A, in the former shift period of the two periods of shift states, the self test circuit 32 is in the state of non-bypass. The FFs 14 of FIG. 10 for outputting #3, #4, and #6 are not bypassed. The FFs 14 transfer the data shifted in by a shift register. In the latter shift period, the self test circuit 32 performs bypass. By the bypass being performed, the FFs 14 for outputting #3, #4, and #6 are bypassed. The Reset signal is made active. The FFs 14 for outputting #2, #5, and #7 are connected to each other.

As shown in FIGS. 11E to 11K, the Reset and the bypass are made active in one shift period. Of A and B surrounded by broken lines in FIGS. 11E to 11K, the symbol A represents a part in which the data are locally changed at the time of non-bypass. The symbol B represents a part in which the data are locally changed at the time of bypass. A result is obtained by running the self test circuit 32 that the toggle rate in B is lower than the toggle rate in A.

The toggle rate is a rate of the number of toggles with respect to the number of clock signals at one node. For example, at the node #4, 5 toggles with respect to 5 clock signals correspond to the toggle rate of 100%. The number of toggle is a number of changes of a voltage level at a node from H to L or L to H.

In the shift period of B, a lower power is consumed due to a fewer number of toggles. The FFs 14 for outputting #3, #4, and #6 remain left with the Reset/Preset being supplied. The data do not change. Only the other FF 14, which are different from resettable/presettable FFs 14, perform scan shift. By the scan shift, the test is performed.

By using the self test circuit 32, the toggle rate is kept low in the shift period B. The self test circuit 32 is effective in that the power consumption during the shift period can be reduced by controlling the toggle rate.

In the semiconductor integrated circuit according to the related art, the data to be shifted in are masked as a countermeasure for low power consumption. In the method of masking, values of all the FFs 14 are partly fixed. An activation rate of the FFs 14 locally gets low. There is a drawback that the fault detection rate cannot be easily improved due to the fixed values and the decrease in the activation rate.

Suppose that the self test circuit 32 asserts only the Reset signal during the shift period without providing any bypass path. In the case that only the Reset signal is asserted, the fixed value of non-presettable FFs 14 being connected to the next stage are transferred to the next stage FFs 14.

An example having no bypass path and using only the Reset signal cannot improve the fault detection rate. In addition, the captured data are not shifted out. In such example, the fault detection rate is decreased more.

With the semiconductor integrated circuit according to the present embodiment, the shift operation to the non-presettable FF 14 is secured. By securing the shift operation, the data can be shifted out. The semiconductor integrated circuit according to the present embodiment becomes operative to reduce the power consumption while minimizing the decrease in the fault detection rate.

By providing a multiplexer 33 and controlling the multiplexer 33 to select the bypass path side at an arbitrary timing during the shift operation, the operating current during the shift operation can be reduced while preventing the decrease in the fault detection rate. The operating current during the operation of logic BIST can be reduced while minimizing the decrease in the detection rate.

Alternatively, in the example of FIG. 10, a device or a circuit having a switching function may be used as a bypass section instead of the multiplexer 33.

The FFs 14 for outputting #3, #4, and #6 in FIG. 10 may be synchronous presettable FFs 14 described in the third embodiment. The method of providing a multiplexer 33 can apply to the example of FIG. 8, in which AND gates 27 and gate circuits 31 are provided in the input paths of the FFs 14.

It should be noted that the above-described embodiments are not limited to what they are, and the embodiments can be embodied on the implementation phase by deforming the components without departing from their spirits.

The number of the FFs 14 constituting the logic pattern is set by either the self test control circuit 22 or the logic BIST control circuit 23.

Although the selectors 15 are provided in the FF 14 in FIG. 3A, the selectors 15 may be provided outside the FF 14.

The definition of the logics in the drawings and the timing charts can be changed in various ways. For example, although active and non-active of the Shift En are L and H, respectively, they may be reversed. Needless to say, the data transition and the capturing of the data can be done at the timing of either the rising edge or the falling edge of the clock signal.

While certain embodiments have been described, these embodiments have been presented by way of example only, and are not intended to limit the scope of the inventions. Indeed, the novel methods and systems described herein may be embodied in a variety of other forms; furthermore various omissions and substitutions and changes in the form of methods and systems described herein may be made without departing from the spirit of the inventions. The accompanying claims and their equivalents are intended to cover such forms or modifications as would fall within the scope and spirits of the inventions.

What is claimed is:

1. A semiconductor integrated circuit, comprising:
a logic circuit including plural combination circuits and plural first flip-flops;
plural selectors for respective first flip-flops configured to switch between first paths from the combination circuits and second paths from previous stage flip-flops of the first flip-flops;
plural scan chains in the logic circuit, each of the scan chains configured to have the second path activated based on selection by the selectors;
a pattern generator configured to generate patterns for test for the scan chains;
a test control circuit configured to drive the pattern generator and cause the plural selectors to switch, the test control circuit performing self test by a result of response from the scan chains; and
plural setting terminals configured to set logic values individually in a combination of a part of second flip-flops, the second flip-flops being representative of a logic pattern and of the first flip-flops in the logic circuit tested by the test control circuit.

2. The semiconductor integrated circuit of claim 1, wherein
the setting terminals are disposed on each of the part of the second flip-flops; and
the setting terminals are reset terminals or preset terminals through which the part of the second flip-flops are instructed from the test control circuit asynchronously with a clock for the logic circuit.

3. The semiconductor integrated circuit of claim 1, wherein
the setting terminals are other logic circuits each provided in an input path for shift data of each of the part of the second flip-flops; and
the other logic circuits input each value in each of the part of the second flip-flops synchronously with a clock from the test control circuit to the logic circuit.

4. The semiconductor integrated circuit of claim 2, further comprising:
bypass sections configured to bypass shift paths provided between the part of the second flip-flops and fourth flip-flops different from the part of the second flip-flops, wherein
the test control circuit controls the bypass sections to bypass or not bypass the shift paths.

5. The semiconductor integrated circuit of claim 3, further comprising:
bypass sections configured to bypass shift paths provided between the part of the second flip-flops and third flip-flops different from the part of the second flip-flops, wherein
the test control circuit controls the bypass sections to bypass or not bypass the shift paths.

6. The semiconductor integrated circuit of claim 2, wherein
after completion of an operation of shifting in of the patterns by the scan chains and before an actual operation, the test control circuit causes the setting terminals to reset or preset the part of the second flip-flops.

7. The semiconductor integrated circuit of claim 3, wherein
the test control circuit causes the other logic circuits to input the each value on a final stage of an operation of shifting-in of the patterns by the scan chains.

8. The semiconductor integrated circuit of claim 4, wherein
the test control circuit causes the bypass sections to bypass the shift paths during an operation of shifting in.

9. The semiconductor integrated circuit of claim 5, wherein
the test control circuit causes the bypass sections to bypass the shift paths during an operation of shifting in.

10. The semiconductor integrated circuit of claim 1, wherein
the part of the second flip-flops are essentially constituted by at least two groups, and
the setting terminals reset or preset the part of the second flip-flops by at least two systems of signals, each of the signals corresponding to each of the two groups from the test control circuit.

11. The semiconductor integrated circuit of claim 1, wherein
the test control circuit comprises:
a storing section configured to store in advance an expected value for random number patterns from the pattern generator;
a read-out section configured to read out data streams of plural systems, each of the data streams is output from each of the scan chains with respect to the patterns for test having a code length equal to a number of steps of shift of each scan chain from the pattern generator; and
a comparator configured to compare the data streams of the systems read out by the read-out section and the expected value in the storing section.

12. The semiconductor integrated circuit of claim 1, wherein
the test control circuit presets the part of the second flip-flops asynchronously with a clock from the test control circuit to the logic circuit.

13. The semiconductor integrated circuit of claim 1, wherein
the test control circuit presets the part of the second flip-flops through input paths for shift data synchronously with a clock from the test control circuit to the logic circuit.

14. A semiconductor integrated circuit, comprising:
a logic circuit including plural combination circuits and plural flip-flops;
plural selectors for respective first flip-flops configured to switch between first paths from the combination circuits and second paths from previous stage flip-flops of the first flip-flops;
plural scan chains in the logic circuit, each of the scan chains configured to have the second path activated based on selection by the selectors;
a pattern generator configured to generate patterns for test for the scan chains;
a test control circuit configured to drive the pattern generator and cause the selectors to switch, the test control circuit performing self test by a result of response from the scan chains; and
plural setting terminals configured to set logic values individually in a combination of a part of second flip-flops which are representative of a logic pattern and of the first flip-flops in the logic circuit tested by the test control circuit, each of the setting terminal being provided either on each of the part of the second flip-flops or in an input path for shift data of each of the part of the second flip-flops; and
bypass sections configured to bypass shift paths provided between the part of the second flip-flops and third flip-flops different from the part of the second flip-flops.

15. A method for self test of semiconductor integrated circuit, the method comprising:
at a logic circuit which includes plural combination circuits and plural first flip-flops, and a test control circuit for built-in self test of the logic circuit, shifting patterns for test into plural scan chains in the logic circuit through first paths from previous stages, for each of the first flip-flops;
setting, at the test control circuit, through setting terminals, individually logic values in a combination of a part of second flip-flops which are representative of a logic pattern and of the first flip-flops in the logic circuit;
causing, at the test control circuit, the logic circuit to actually operate by supply of a clock through a second path from the combination circuits for each of the first flip-flops; and
checking, at the test control circuit, whether an operation is normal or not, based on data shifted out from the scan chains and previously stored expected value data.

16. The method of claim 15, wherein
in setting the logic values, the part of the second flip-flops are reset or preset asynchronously with the clock.

17. The method of claim 15, wherein
in setting the logic values, inputting, at other logic circuit provided in an input path for shift data for each of the first flip-flops, each value in the part of the second flip-flops synchronously with the clock.

18. The method of claim 15, wherein
before shifting in the patterns, determining whether to bypass or not to bypass shift paths provided from the part of the second flip-flops to third flip-flops different from the part of the second flip-flops.

19. The method of claim 15, wherein
after shifting in of the patterns is completed and before an actual operation of the logic circuit is started, the setting terminals reset or preset the part of the second flip-flops.

20. The method of claim 15, wherein
on a final stage of shifting in of the patterns, inputting, at other logic circuits each provided in an input path for shift data for each of the first flip-flops, each value in the part of the second flip-flops.
